(19) United States
(12) Patent Application Publication
(10) Pub. No.: US 2025/0201441 A1
(43) Pub. Date: Jun. 19, 2025

(54) WIRE HARNESS

(71) Applicants: AUTONETWORKS TECHNOLOGIES, LTD., Yokkaichi-shi, Mie (JP); SUMITOMO WIRING SYSTEMS, LTD., Yokkaichi-shi, Mie (JP); SUMITOMO ELECTRIC INDUSTRIES, LTD., Osaka-shi, Osaka (JP)

(72) Inventor: Naoya HAMAMOTO, Yokkaichi-shi (JP)

(73) Assignees: AUTONETWORKS TECHNOLOGIES, LTD., Yokkaichi-shi, Mie (JP); SUMITOMO WIRING SYSTEMS, LTD., Yokkaichi-shi, Mie (JP); SUMITOMO ELECTRIC INDUSTRIES, LTD., Osaka-shi, Osaka (JP)

(21) Appl. No.: 18/849,178

(22) PCT Filed: Mar. 23, 2023
(86) PCT No.: PCT/JP2023/011411

§ 371 Date: Sep. 20, 2024

(30) Foreign Application Priority Data
Apr. 1, 2022 (JP) 2022-061817

(51) Int. Cl. H01B 7/00; B60R 16/02; H01B 7/18; H01B 7/20; H01B 7/22; H01B 7/282; H01B 7/36; H01B 9/02; H01B 13/012; H02G 3/04

(52) U.S. Cl. CPC H01B 7/0045; B60R 16/0207; H01B 7/184; H01B 7/207; H01B 7/228; H01B 7/2825; H01B 7/361; H01B 9/024; H01B 13/01209; H02G 3/0481

(57) ABSTRACT

A wire harness that includes an electric wire; a metal braid that covers an outer periphery of the electric wire along a direction of extension of the electric wire; and a metal pipe penetrated both by the electric wire and the metal braid. In addition, a length of the metal braid in the direction of extension of the electric wire can be longer than a length of the metal pipe in the direction of extension of the electric wire.

### TECHNICAL FIELD

The present disclosure relates to a wire harness.

### BACKGROUND ART

Conventional wire harnesses include electric wires, a metal braided member covering the outer peripheries of the electric wires in a first range along the direction of the extension of the electric wires, and a metal pipe connected to one end of the metal braided member and covering the outer peripheries of the electric wires in a second range along the direction of the extension of the electric wires (see, for example, Patent Document 1). In such a wire harness, the metal pipe restricts the routing of the electric wires, and the metal braided member ensures the flexibility of the electric wires. Furthermore, in such a wire harness, electromagnetic radiation is suppressed over a long range in the direction of the extension of the electric wires by the cooperation of the metal braided member and the metal pipe connected in the direction of the extension of the electric wires.

### CITATION LIST

### Patent Documents

Patent Document 1: JP 2006-310516A

### SUMMARY OF INVENTION

### Technical Problem

In recent years, in order to reduce vehicle weight, attempts have been made to change the body material from steel to carbon, for example. In this case, as it is difficult for the body to absorb electromagnetic waves, the wire harness is required to further suppress electromagnetic radiation by itself.

The present disclosure has been made to solve the above-identified problem, and an object thereof is to provide a wire harness capable of further suppressing electromagnetic radiation.

### Solution to Problem

A wire harness according to the present disclosure includes: an electric wire; a metal braided member covering an outer periphery of the electric wire along a direction of extension of the electric wire; and a metal pipe penetrated both by the electric wire and the metal braided member.

### Advantageous Effects of Invention

The wire harness of the present disclosure is capable of further suppressing electromagnetic radiation.

### BRIEF DESCRIPTION OF DRAWINGS

FIG. 1 is a schematic configuration view of a vehicle according to one embodiment.

FIG. 2 is a partial plan view of the wire harness according to the embodiment.

FIG. 3 is a cross-sectional view taken on line 3-3 of FIG. 2.

FIG. 4 is a partial plan view of the wire harness according to the embodiment during its manufacturing process.

FIG. 5 is a partial plan view of the wire harness according to the embodiment during its manufacturing process.

FIG. 6 is a partial plan view of the wire harness according to the embodiment during its manufacturing process.

### DESCRIPTION OF EMBODIMENTS

### Description of Embodiments of Present Disclosure

First, embodiments of the present disclosure will be listed and described.

A wire harness according to the present disclosure includes:

(1) an electric wire; a metal braided member covering an outer periphery of the electric wire along a direction of extension of the electric wire; and a metal pipe penetrated both by the electric wire and the metal braided member.

According to this configuration, the electrical wire is doubly covered by the metal braided member and the metal pipe. Therefore, the radiation of electromagnetic waves can be further suppressed compared to the case where the electrical wire is covered only with the metal braided member or only with the metal pipe.

(2) Preferably, a length of the metal braided member in the direction of the extension of the electric wire is longer than a length of the metal pipe in the direction of the extension of the electric wire.

According to this configuration, as the entire region of the electric wire in the metal pipe along the direction of the extension of the electric wire is also covered by the metal braided member, electromagnetic radiation can be further suppressed in the entire region of the electric wire. Furthermore, as the metal braided member extends out of the metal pipe, the metal braided member can be easily connected to another component.

(3) Preferably, one end of the metal braided member in the direction of the extension of the electric wire has a folded-back portion that is folded back at one end of the metal pipe in the direction of the extension of the electric wire and connected to an outer peripheral surface of the metal pipe,

According to this configuration, the folded-back portion of the metal braided member can facilitate the connection of the metal braided member to the metal pipe.

(4) Preferably, the outer peripheral surface of the metal pipe has a painted portion painted to indicate that it is for high-voltage electric wires, and an unpainted portion where the metal is exposed to which the folded-back portion is connected.

According to this configuration, the painted portion indicates that it is for high-voltage electric wires, and the unpainted portion can facilitate the connection of the metal braided member to the metal pipe.

(5) Preferably, at least one of the metal braided member and the metal pipe is made of an iron-based metal material.

According to this configuration, if the common iron-based metal material of the body of the vehicle with the wire harness installed thereon is replaced by another material, it is possible to suppress the radiation of electromagnetic waves in the frequency band of concern. That is, if the common iron-based metal material of the body of the vehicle is replaced by another material, the electromagnetic waves in the frequency band that would otherwise be absorbed by the body may not be easily absorbed, thus raising a concern of the adverse effects of the electromagnetic waves in that frequency band. In contrast, it is possible to suppress the radiation of electromagnetic waves in that frequency band with the wire harness.

(6) Preferably, the metal braided member and the metal pipe are made of metal materials different from each other.

According to this configuration, it is possible to suppress the radiation of electromagnetic waves in a wide range of frequency bands.

(7) Preferably, the metal braided member is made of a copper-based or aluminum-based metal material, and the metal pipe is made of an ion-based metal material.

According to this configuration, it is possible to suppress the radiation of electromagnetic waves in a wide range of frequency bands. Furthermore, if the common iron-based metal material of the body of the vehicle with the wire harness installed thereon is replaced by another material, it is possible to suppress the radiation of electromagnetic waves in the frequency band of concern. That is, if the common iron-based metal material of the body of the vehicle is replaced by another material, the electromagnetic waves in the frequency band that would otherwise be absorbed by the body may not be easily absorbed, thus raising a concern of the adverse effects of the electromagnetic waves in that frequency band. In contrast, it is possible to suppress the radiation of the electromagnetic waves in that frequency band with the wire harness.

(8) Preferably, the metal braided member is a first metal braided member; the wire harness further includes: a second metal braided member covering a different region of the outer periphery of the electric wire along the direction of the extension of the electric wire from where it is covered by the first metal braided member; and a sheath member penetrated both by the electric wire and the second metal braided member.

According to this configuration, radiation of the electromagnetic waves can be suppressed from the electrical wire where it is covered by the second metal braided member.

(9) Preferably, the wire harness further includes a fixing member configured to connect the first metal braided member to the second metal braided member and to fix the first and second metal braided members.

According to this configuration, the first metal braided member and the second metal braided member can be easily connected without performing any troublesome work, such as welding.

(10) Preferably, a length of the first metal braided member in the direction of the extension of the electric wire is longer than a length of the metal pipe in the direction of the extension of the electric wire; one end of the first metal braided member in the direction of the extension of the electric wire has a folded-back portion that is folded back at one end of the metal pipe in the direction of the extension of the electric wire and connected to an outer peripheral surface of the metal pipe, one end of the second metal braided member in the direction of the extension of the electric wire has a covering portion that covers the folded-back portion; and the fixing member is a crimping member disposed to surround the metal pipe, the folded-back portion, and the covering portion with the metal pipe as a base of the crimping member, the fixing member being fixed by crimping.

According to this configuration, as the entire region of the electric wire in the first metal pipe along the direction of the extension of the electric wire is also covered by the metal braided member, electromagnetic radiation can be further suppressed in the entire region of the electric wire. Furthermore, the folded-back portion of the first metal braided member and the covering portion of the second metal braided member are collectively connected to the metal pipe by crimping the member to the metal pipe, which serves as the base. As a result, compared with the case in which the first metal braided member, the second metal braided member, and the metal pipe are connected at two or more locations, it is possible to reduce the number of manufacturing steps and simplify the configuration.

(11) Preferably, the wire harness further includes a waterproof member configured to collectively cover a portion of the metal pipe with which the folded-back portion comes into contact, the folded-back portion, the covering portion, and the crimping member.

According to this configuration, the waterproof member collectively prevents the portion of the metal pipe with which the folded-back portion comes into contact, the folded-back portion, the covering portion, and the crimping member from being exposed to water.

### Details of Embodiments of Present Disclosure

Specific examples of the wire harness of the present disclosure will be described below with reference to the drawings. In each drawing, for convenience of description, portions of the configuration may be exaggerated or simplified. Also, the dimensional proportion of each portion may differ from figure to figure. In the present specification, “parallel”, “orthogonal”, and “perfectly circular” include not only the case of being strictly orthogonal, parallel, and a perfect circle, but also the case of being approximately orthogonal, parallel, and perfectly circular within the range in which the actions and effects of the present embodiment are achieved. Note that the present invention is not limited to these examples, and is indicated by the claims, and is intended to include all modifications within the meaning and range of equivalency to the claims.

### General Configuration of Wire Harness 10

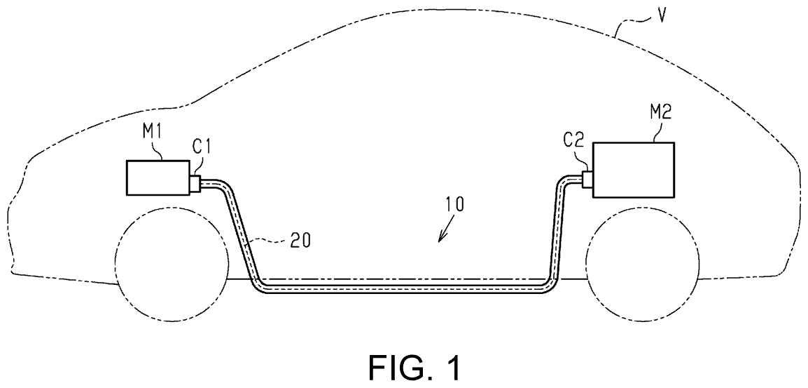

As shown in FIG. 1, a wire harness 10 is to be mounted on a vehicle V, such as a hybrid vehicle or an electric vehicle, for example. The wire harness 10 electrically connects two or more on-board devices to each other. The on-board devices are electric devices mounted on the vehicle V. The wire harness 10 electrically connects, for example, an inverter M1 installed in a front portion of the vehicle V and a high-voltage battery M2 installed in a rear portion of the vehicle V. The wire harness 10 is formed in an elongated shape so as to extend in a front-rear direction of the vehicle V, for example. The wire harness 10 is routed through the vehicle V so that, for example, an intermediate portion in the direction of extension of the wire harness 10 passes outside the vehicle interior, such as under the floor of the vehicle V.

The inverter M1 is, for example, connected to a motor (not shown) for driving the wheels, which serves as a power source when the vehicle travels. The inverter M1 generates AC power from the DC power of the high-voltage battery M2, and supplies the AC power to the motor. The high voltage battery M2 is, for example, a battery capable of supplying a voltage of several hundred volts.

### Configuration of Wire Harness 10

The wire harness 10 includes electric wires 20. The wire harness 10 has connectors C1 and C2 attached to both ends of the electric wires 20. One end of each electric wire 20 in the direction of the extension thereof is connected to the inverter M1 via the connector C1. The other end of each electric wire 20 in the direction of the extension thereof is connected to the high-voltage battery M2 via the connector C2.

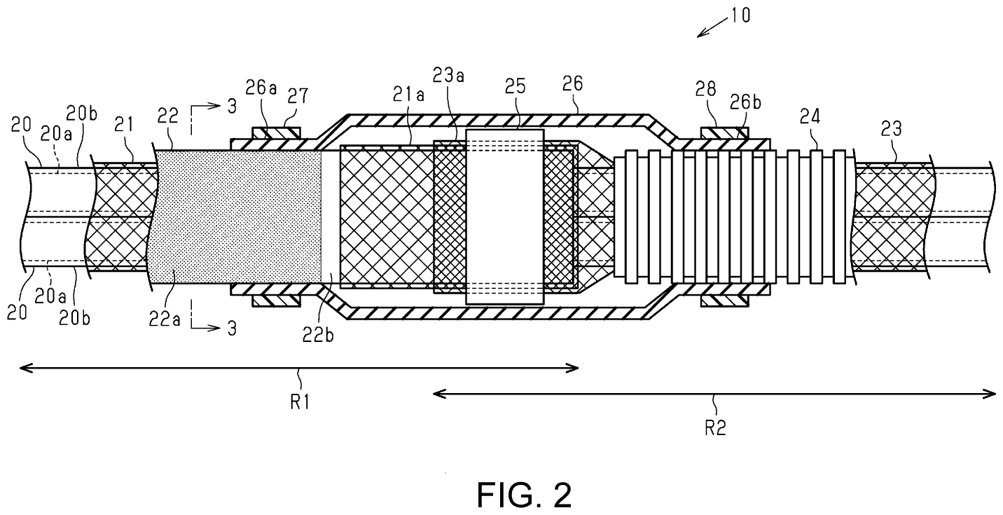

As shown in FIG. 2, the wire harness 10 has a metal braided member such as a first metal braided member 21, a metal pipe 22, a second metal braided member 23, a sheath member 24, a fixing member such as a crimping member 25, and a waterproof member 26.

### Configuration of Electric Wires 20

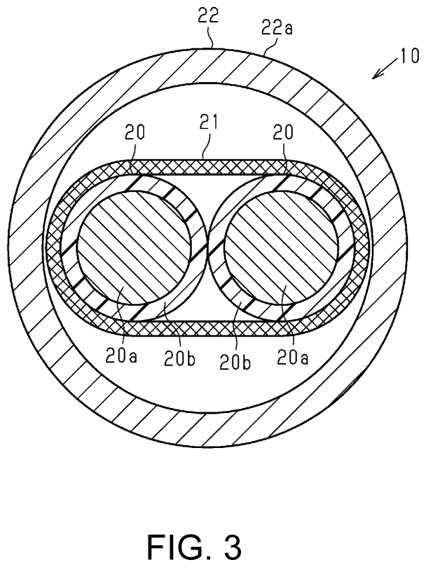

As shown in FIG. 3, the electric wires 20 each have a core wire 20a and an insulating coating 20b that covers the outer periphery of the core wire 20a. The wire harness 10 of the present embodiment includes two electric wires 20. The electric wires 20 are high-voltage electric wires that can carry a high voltage and a large current.

### Configuration of First Metal Braided Member 21

The first metal braided member 21 covers the outer peripheries of the electrical wires 20 along the direction of the extension of the electric wires 20. The first metal braided member 21 of the present embodiment covers the two electric wires 20 together. The first metal braided member 21 collectively suppresses the electromagnetic radiation from the two electric wires 20. The first metal braided member 21 of the present embodiment is made of a copper-based metal material with copper as its main component. The first metal braided member 21 is a braided electric wire in which the strands made of a copper-based metal material are braided into a cylindrical shape. It should be noted that the first metal braided member 21 can be folded, bundled, expanded in its diameter, or deformed, and each figure is a schematic illustration thereof.

### Configuration of Metal Pipe 22

The electric wires 20 and the first metal braided member 21 both penetrate the metal pipe 22. In other words, the outer periphery of the first metal braided member 21, which covers the electric wires 20, is further covered by the metal pipe 22. The metal pipe 22 of the present embodiment is formed in the shape of a perfectly circular cylinder. The metal pipe 22 collectively suppresses the electromagnetic radiation from the two electric wires 20. The metal pipe 22 is made of a metal material different from that of the first metal braided member 21. The metal pipe 22 of the present embodiment is made of an iron-based metal material with iron as its main component.

As shown in FIG. 2, the outer peripheral surface of the metal pipe 22 has a painted portion 22a painted to indicate that it is for high-voltage electric wires, and an unpainted portion 22b that remains unpainted and has exposed metal. The unpainted portion 22b is provided on an end in the direction of the extension of the metal pipe 22. It should be noted that the metal pipe 22, the electric wire 20, and the first metal braided member 21 extend all in the same direction. Furthermore, the color of the paint of the painted portion 22a is orange in the present embodiment. The metal pipe 22 of the present embodiment is laid to run under the floor of the vehicle V, for example, and restricts the path of the electric wires 20, such as by limiting the sagging of the electric wire 20.

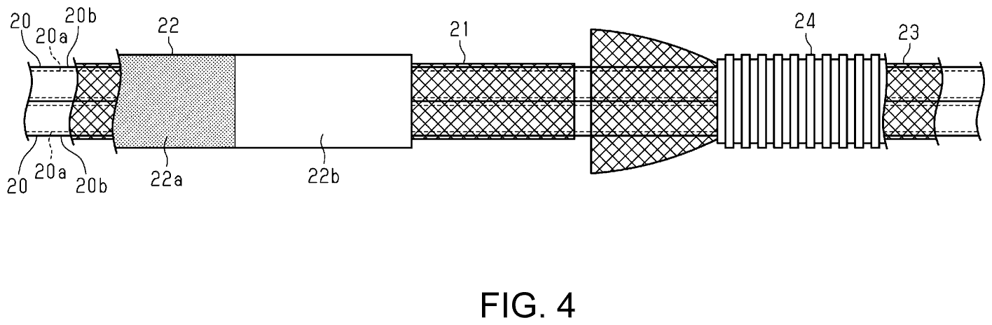

As shown in FIG. 4, the first metal braided member 21 is longer than the metal pipe 22. It should be noted that FIG. 4 shows the first metal braided member 21, etc., during the manufacturing process of the wire harness 10. Although not shown in FIG. 4, the first metal braided member 21 of the present embodiment protrudes outward from both ends of the metal pipe 22 in the direction of the extension of the metal pipe 22.

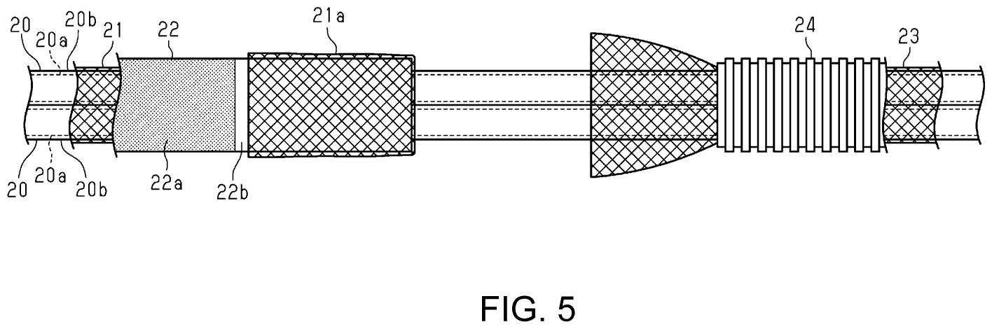

As shown in FIG. 5, one end in the direction of the extension of the first metal braided member 21 has a folded-back portion 21a that is folded back at the end of the metal pipe 22 in the direction of the extension thereof and connected to the outer peripheral surface of the metal pipe 22. It should be noted that FIG. 5 shows the first metal braided member 21, etc., during the manufacturing process of the wire harness 10 after the step shown FIG. 4. The folded-back portion 21a is connected to the unpainted portion 22b of the metal pipe 22.

### Configuration of Second Metal Braided Member 23

As shown in FIG. 2, the second metal braided member 23 covers regions of the outer peripheries of the electric wires 20 along the direction of the extension of the electric wires 20 that are different from where they are covered by the first metal braided member 21. A first region R1 where the first metal braided member 21 covers the electric wires 20 and a second region R2 where the second metal braided member 23 covers the electric wires 20 overlap in part. The second metal braided member 23 of the present embodiment covers the two electric wires 20 together. The second metal braided member 23 collectively suppresses the electromagnetic radiation from the two electric wires 20. The second metal braided member 23 of the present embodiment is made of a copper-based metal material with copper as its main component. The second metal braided member 23 is a braided electric wire in which the strands made of a copper-based metal material are braided into a cylindrical shape. It should be noted that the second metal braided member 23 can be folded, gathered, expanded in its diameter, or deformed, and each figure is a schematic illustration thereof.

### Configuration of Sheath Member 24

The electric wires 20 and the second metal braided member 23 both penetrate the sheath member 24. In other words, the outer periphery of the second metal braided member 23, which covers the electric wires 20, is further covered by the sheath member 24. The sheath member 24 of the present embodiment is a flexible and easily bendable corrugated tube. In other words, the sheath member 24 is made of resin and has a bellows shape alternating with small and large diameters in the direction of the extension thereof. The sheath member 24 of the present embodiment is disposed, for example, in a location where it is bent from under the floor of the vehicle V upward in the vehicle V.

As shown in FIG. 4, the second metal braided member 23 is longer that the sheath member 24. It should be noted that although not shown in FIG. 4, the second metal braided member 23 of the present embodiment protrudes outward from both ends of the sheath member 24 in the direction of the extension of the sheath member 24.

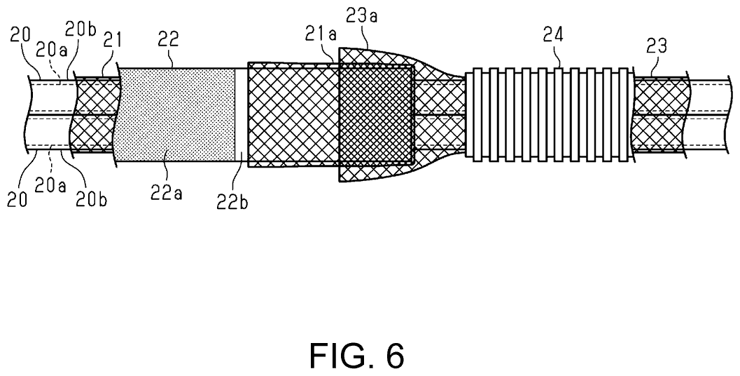

As shown in FIG. 6, one end of the second metal braided member 23 in the direction of the extension thereof has a covering portion 23a that covers the folded-back portion 21a. The covering portion 23a is disposed so that its enlarged diameter outside the sheath member 24 covers the folded-back portion 21a. It should be noted that FIG. 6 shows the first metal braided member 21 and the second metal braided member 23, etc., during the manufacturing process of the wire harness 10 after the step shown FIG. 5.

### Configurations of Crimping Member 25

As shown in FIG. 2, the crimping member 25 connects the first metal braided member 21 to the second metal braided member 23 and fixed them. In particular, the crimping member 25 is comprised of a metal ring. The crimping member 25 is disposed to surround the metal pipe 22, the metal pipe 22, the folded-back portion 21a, and the covering portion 23a with the metal pipe as a base of the crimping member, and is fixed by crimping. That is, the folded-back portion 21a and the covering portion 23a are sandwiched between the metal pipe 22 and the crimping member 25 and electrically connected to the metal pipe 22. It should be noted that the overlapping region between the first region R1 and the second region R2 is where the covering portion 23a covers the folded-back portion 21a.

### Configurations of Waterproof Member 26

The waterproof member 26 collectively covers the portion of the metal pipe 22 with which the folded-back portion 21a comes into contact, i.e., the unpainted portion 22b, the folded-back portion 21a, the covering portion 23a, and the crimping member 25. The waterproof member 26 of the present embodiment is made of a resilient member, such as rubber material, formed in a tubular shape. The waterproof member 26 is disposed so that one end 26a thereof in the direction of its extension covers the outer periphery of the painted portion 22a of the metal pipe 22 and the other end 26b thereof in the direction of its extension covers the outer periphery of the sheath member 24. The waterproof member 26 is also secured in intimate contact with the outer periphery of the painted portion 22a of the metal pipe 22 by tightening the outer periphery of the end 26a with a binding band 27 made of resin. Additionally, the waterproof member 26 is secured in intimate contact with the outer periphery of the sheath member 24 by tightening the outer periphery of the other end 26b thereof with a binding band 28 made of resin.

The following describes the operation of the wire harness 10 configured as described above.

Electromagnetic radiation is suppressed as the portions of the electrical wires 20 corresponding to the metal pipe 22 are covered by the metal pipe 22 and the first metal braided member 21. Moreover, electromagnetic radiation is suppressed as the portions of the electrical wires 20 corresponding to the sheath member 24 are covered by the second metal braided member 23.

The following describes the effects of the foregoing embodiment.

(1) The electrical wires 20 are doubly covered by the first metal braided member 21 and the metal pipe 22. Therefore, for example, the radiation of electromagnetic waves can be further suppressed compared to the case where the electrical wires 20 are covered only with the first metal braided member 21 or only with the metal pipe 22.

(2) The length of the first metal braided member 21 in the direction of the extension of the electric wires 20 is greater than the length of the metal pipe 22 in the direction of the extension of the electric wires 20. In this way, since all the regions of the electric wires 20 in the metal pipe 22 are also covered by the first metal braided member 21 along the direction of their extension, the electromagnetic radiation can be further suppressed from all the regions of the electric wires. Furthermore, as the first metal braided member 21 extends out of the metal pipe 22, the first metal braided member 21 can be, for example, easily connected to another component.

(3) One end of the first metal braided member 21 in the direction of the extension of the electric wires 20 has a folded-back portion 21a that is folded back at one end of the metal pipe 22 in the direction of the extension of the electric wires 20 and connected to the outer peripheral surface of the metal pipe 22. As such, the folded-back portion 21a can facilitate the connection of the first metal braided member 21 to the metal pipe 22.

(4) The outer peripheral surface of the metal pipe 22 has a painted portion 22a painted to indicate that it is for high-voltage electric wires, and an unpainted portion 22b where the metal is exposed to which the folded-back portion 21a is connected. As such, the painted portion 22a indicates that it is for high-voltage electric wires, and the unpainted portion 22b can facilitate the connection of the folded-back portion 21a of the first metal braided member 21 to the metal pipe 22.

(5) The first metal braided member 21 is made of a copper-based metal material, and the metal pipe 22 is made of an iron-based metal material. In this way, as the first metal braided member 21 and the metal pipe 22 are made of metal materials different from each other, it is possible to suppress the radiation of electromagnetic waves in a wide range of frequency bands. Additionally, if the common iron-based metal material of the body of the vehicle V with the wire harness 10 installed thereon is replaced by, for example, a material such as carbon or an aluminum-based metal material, it is possible to suppress the radiation of electromagnetic waves in the frequency band of concern. That is, if the common iron-based metal material of the body of the vehicle V is replaced by a material such as carbon or an aluminum-based metal material, the electromagnetic waves in the frequency band that would otherwise be absorbed by the body may not be easily absorbed, thus raising a concern of the adverse effects of the electromagnetic waves in that frequency band. In contrast, the metal pipe 22 made of an iron-based metal material is capable of suppressing the radiation of electromagnetic waves in that frequency band.

(6) The radiation of electromagnetic waves can be suppressed from the electrical wires 20 where they are covered by the second metal braided member 23.

(7) Since the crimping member 25 is included that connects the first metal braided member 21 to the second metal braided member 23 and fixes them, for example, the first metal braided member 21 and the second metal braided member 23 can be easily connected without performing any troublesome work, such as welding.

(8) The folded-back portion 21a of the first metal braided member 21 and the covering portion 23a of the second metal braided member 23 are collectively connected to the metal pipe 22 by crimping the crimping member 25 to the metal pipe 22, which serves as the base. As a result, for example, compared with the case in which the first metal braided member 21, the second metal braided member 23, and the metal pipe 22 are connected at two or more locations, it is possible to reduce the number of manufacturing steps and simplify the configuration.

(9) The waterproof member 26 collectively prevents the portion of the metal pipe 22 with which the folded-back portion 21a comes into contact, the folded-back portion 21a, the covering portion 23a, and the crimping member 25 from being exposed to water. In the present embodiment, although the first metal braided member 21 and the metal pipe 22 are made of different metal materials, galvanic corrosion is prevented by preventing their exposure to water.

The present embodiment may be practiced with the modifications below. The present embodiment and the modifications below may be practiced in combination to the extent that they are technically compatible.
In the above-described embodiment, although the length of the first metal braided member 21 in the direction of the extension thereof is longer than the metal pipe 22 in the direction of the extension thereof, and the first metal braided member 21 has, on one end thereof, a folded portion 21a that is folded back and connected to the outer peripheral surface of the metal pipe 22, the present invention is not limited to this.

For example, the length of the first metal braided member 21 in the direction of the extension thereof may be shorter than the length of the metal pipe 22 in the direction of the extension thereof. Furthermore, for example, the first metal braided member 21 may not have a folded portion 21a on one end thereof. For example, the first metal braided member 21 may be configured for connection to the inner peripheral surface of the metal pipe 22.
In the above-described embodiment, although the outer peripheral surface of the metal pipe 22 has a painted portion 22a and an unpainted portion 22b, the present invention is not limited to this. For example, the metal pipe 22 may not be configured with the painted portion 22a. Moreover, for example, the first metal braided member 21 may be connected to the inner peripheral surface of the metal pipe 22, and the entire outer peripheral surface of the metal pipe 22 may have a painted portion 22a thereon without including an unpainted portion 22b.
In the above-described embodiment, although the first metal braided member 21 is made of a copper-based metal material and the metal pipe 22 is made of an iron-based metal material, these may be made of other metal materials. For example, the first metal braided member 21 may be made of an aluminum-based metal material with aluminum as its main component. Moreover, for example, the first metal braided member 21 may also be made of an iron-based metal material. Moreover, for example, the metal pipe 22 may also be made of an aluminum-based metal material. Moreover, for example, the metal pipe 22 may also be made of a copper-based metal material. Furthermore, the combination of the metal materials forming the first metal braided member 21 and the metal pipe 22 may be changed in any way.
In the above-described embodiment, although the wire harness 10 is configured to include the second metal braided member 23, the present invention is not limited to this; rather, a configuration without the second metal braided member 23 will also suffice. Moreover, in the above-described embodiment, although the second metal braided member 23 is made of a copper-based metal material, the present invention is not limited to this; rather, it may be made of another metal material. For example, the second metal braided member 23 may also be made of an aluminum-based metal material. Moreover, for example, the second metal braided member 23 may also be made of an iron-based metal material.
In the above-described embodiment, although the wire harness 10 is configured to include the sheath member 24, the present invention is not limited to this; rather, a configuration without the sheath member 24 will also suffice. Moreover, in the above-described embodiment, although the sheath member 24 is a corrugated tube, the present invention is not limited to this; rather, it may be made of another type of sheath member.
Although the above-described embodiment includes the crimping member 25, which serves as a fixing member that connects the first metal braided member 21 to the second metal braided member 23 and fixes them, the present invention is not limited to this. For example, a C-ring formed in a C-shape may be used as the fixing member that connects the first metal braided member 21 to the second metal braided member 23 and fixes them. Moreover, for example, no fixing member, such as the crimping member 25, etc., may be included, so that the first metal braided member 21 and the second metal braided member 23 may be connected and fixed by welding.
In the above-described embodiment, although the crimping member 25 is fixed by crimping with the metal pipe 22 as the base, the present invention is not limited to this, for example, it may be secured using an underlay ring that is separate from the metal pipe 22 as the base.
In the above-described embodiment, although the wire harness 10 includes a waterproof member 26, the present invention is not limited to this, rather, a configuration without the waterproof member 26 will also suffice. Moreover, the waterproof member 26 may be replaced by another configuration, for example, a shrink tube, as long as it is capable of collectively preventing the portion of the metal pipe 22 with which the folded-back portion 21a comes into contact, the folded-back portion 21a, the covering portion 23a, and the crimping member 25 from being exposed to water.
In the above-described embodiment, although the wire harness 10 includes two electric wires 20, the present invention is not limited to this; rather, the number of the electric wires 20 included in the wire harness 10 may be one, three or more.
In the above-described embodiment, although the first metal braided member 21 collectively covers the two electric wires 20, the present invention is not limited to this; rather, the plurality of electric wires 20 may be individually covered. That is, the wire harness 10 may include a plurality of first metal braided members 21 that match the number of the electrical wires 20.
In the above-described embodiment, although the second metal braided member 23 collectively covers the two electric wires 20, the present invention is not limited to this; rather, the plurality of electric wires 20 may be individually covered. That is, the wire harness 10 may include a plurality of second metal braided members 23 that match the number of the electrical wires 20.
Although the electric wires 20 of the above-described embodiment are high-voltage electric wires, the present invention is not limited to this; for example, the electric wires 20 may be low-voltage electric wires.
In the above-described embodiment, although the metal pipe 22 is laid to run under the floor of the vehicle V, etc., the present invention is not limited to this; rather, it may be laid on another location of the vehicle V.

The phrase “at least one” as used in the present disclosure means “one or more” of desired options. As an example, if there are two options, the phrase “at least one” as used in the present disclosure means “only one option” or “both of the two options”. As another example, if there are three or more options, the phrase “at least one” as used in the present disclosure means “only one option” or “any combination of two or more of the options”.
The present disclosure also encompasses the embodiments set forth below. It should be noted that reference numerals are used to denote the components of the above-described embodiments for the purpose of merely aiding understanding rather than limitation.

### (Appendix 1)

A wire harness (10) including:
electric wires (20);
a metal braided member (21) covering outer peripheries of the electric wires (20) along a direction of extension of the electric wires; and
a metal pipe (22) covering outer peripheries of the metal braided member (21) along the direction of the extension of the electric wires (20);
wherein the metal braided member (21) covers entire regions of the electric wires in the metal pipe (22) along the direction of the extension of the electric wires (20).

### (Appendix 2)

The wire harness according to Appendix 1, wherein the metal braided member (21) is a first metal braided member (21);
including a second metal braided member (22) covering different regions of the outer peripheries of the electric wires (20) along the direction of the extension of the electric wires from where they are covered by the first metal braided member (21); and
a sheath member (24) penetrated both by the electric wires (20) and the second metal braided member (23);
wherein the sheath member (24) is a flexible member; and
the second metal braided member (23) covers regions of the electric wires (20) between the sheath member (24) and the metal pipe (22) and is connected to the metal braided member (21).

### LIST OF REFERENCE NUMERALS

10 Wire harness
20 Electrical wire
20a Core wire
20b Insulating coating
21 First metal braided member (metal braided member)
21a Folded-back portion
22 Metal pipe
22a Painted portion
22b Unpainted portion
23 Second metal braided member
23a Covering portion
24 Sheath member
25 Crimping member (fixing member)
26 Waterproof member
26a End
26b End
27 Binding band
28 Binding band
C1 Connector
C2 Connector
M1 Inverter
M2 High-voltage battery
R1 First region
R2 Second region
V: Vehicle

1. A wire harness comprising:
an electric wire;
a metal braid that covers an outer periphery of the electric wire along a direction of extension of the electric wire; and
a metal pipe penetrated both by the electric wire and the metal braid.

2. The wire harness according to claim 1, wherein a length of the metal braid in the direction of extension of the electric wire is longer than a length of the metal pipe in the direction of extension of the electric wire.

3. The wire harness according to claim 2, wherein one end of the metal braid in the direction of extension of the electric wire has a folded-back portion that is folded back at one end of the metal pipe in the direction of extension of the electric wire and connected to an outer peripheral surface of the metal pipe.

4. The wire harness according to claim 3, wherein the outer peripheral surface of the metal pipe has a painted portion painted to indicate that the metal pipe is for high-voltage electric wires, and an unpainted portion where metal is exposed to which the folded-back portion is connected.

5. The wire harness according to claim 1, wherein at least one of the metal braid and the metal pipe is made of an iron-based metal material.

6. The wire harness according to claim 1, wherein the metal braid and the metal pipe are made of metal materials different from each other.

7. The wire harness according to claim 1, wherein:
the metal braid is made of a copper-based or aluminum-based metal material, and
the metal pipe is made of an ion-based metal material.

8. The wire harness according to claim 1, wherein:
the metal braid is a first metal braid, and
the wire harness further comprises:
a second metal braid that covers a different region of the outer periphery of the electric wire along the direction of extension of the electric wire from where the electric wire is covered by the first metal braid; and
a sheath penetrated both by the electric wire and the second metal braid.

9. The wire harness according to claim 8, further comprising a fixing member that connects the first metal braid to the second metal braid and fixes the first and second metal braids.

10. The wire harness according to claim 9, wherein
a length of the first metal braid in the direction of extension of the electric wire is longer than a length of the metal pipe in the direction of extension of the electric wire,
one end of the first metal braid in the direction of extension of the electric wire has a folded-back portion that is folded back at one end of the metal pipe in the direction of extension of the electric wire and connected to an outer peripheral surface of the metal pipe,
one end of the second metal braid in the direction of extension of the electric wire has a cover that covers the folded-back portion, and
the fixing member is a crimping member disposed to surround the metal pipe, the folded-back portion, and the cover with the metal pipe as a base of the crimping member, the fixing member being fixed by crimping.

11. The wire harness according to claim 10, further comprising a waterproof member that collectively covers a portion of the metal pipe with which the folded-back portion comes into contact, the folded-back portion, the cover, and the crimping member.
